(19) United States
(12) Patent Application Publication
(10) Pub. No.: US 2016/0359461 A1
(43) Pub. Date: Dec. 8, 2016

(54) FRONT END MODULE LOCATED ADJACENT TO ANTENNA IN APPARATUS CONFIGURED FOR WIRELESS COMMUNICATION

(71) Applicant: QUALCOMM Incorporated, San Diego, CA (US)

(72) Inventors: Xiaoyin He, San Diego, CA (US); Vladimir Aparin, San Diego, CA (US); Mohammad Ali Tassoudji, San Diego, CA (US); Joseph Patrick Burke, Glenview, IL (US); Jeremy Darren Dunworth, La Jolla, CA (US)

(21) Appl. No.: 14/732,418

(22) Filed: Jun. 5, 2015

(51) Int. Cl. H03F 3/21; H03F 3/19

(52) U.S. Cl. CPC H03F 3/211; H03F 3/19; H03F 2200/451; H03F 2200/294

(57) ABSTRACT

Various aspects of the present disclosure provide an apparatus for wireless communication. The apparatus may include an integrated circuit, an antenna, and a module located adjacent to the antenna. The module may include at least one of a power amplifier or a low-noise amplifier. The power amplifier may be configured to amplify a signal received from the integrated circuit for transmission by the antenna. The low-noise amplifier may be configured to amplify a signal received from the antenna for reception by the integrated circuit. The module may be separate from the integrated circuit. A length of a feed line connecting the antenna and the module may be less than a length of a feed line connecting the module and the integrated circuit. The module may also include a switching mechanism configured to switch operation of the module between transmission and reception.

### TECHNICAL FIELD

The present disclosure relates generally to an apparatus for wireless communication and, more particularly, to a front end module located adjacent to an antenna in an apparatus configured for wireless communication.

### INTRODUCTION

Wireless communication systems are widely deployed to provide various telecommunication services such as telephony, video, data, messaging, and broadcasts. Wireless technologies have undergone many stages of improvement in various telecommunication standards, each providing protocols that enable various mobile devices to communicate on a municipal, national, regional, and global level. Wireless communication systems may include various mobile devices and network nodes.

Mobile devices may include various components arranged in various configurations. Prior to transmitting a wireless signal to a network node, a mobile device may amplify that signal using its various components. Sometimes, such components may produce heat during signal amplification. In some circumstances, hot/heat spots may cause performance degradation and/or component failure. Also, in some circumstances, the amplified signal may experience path loss. Enhancements pertaining to such aspects can improve system performance and the overall user experience.

### BRIEF SUMMARY OF SOME EMBODIMENTS

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In an aspect, the present disclosure provides an apparatus for wireless communication. The apparatus may include an integrated circuit, an antenna, and a module located adjacent to the antenna. The module may include at least one of a power amplifier or a low-noise amplifier. The power amplifier may be configured to amplify a signal received from the integrated circuit for transmission by the antenna. The low-noise amplifier may be configured to amplify a signal received from the antenna for reception by the integrated circuit.

In another aspect, the present disclosure provides another apparatus for wireless communication. The apparatus may include a means for signal processing, a means for signal transmission, and a means for signal control located adjacent to the means for signal transmission. The means for signal control may include at least one of a power amplifier or a low-noise amplifier. The power amplifier may be configured to amplify a signal received from the means for signal processing for transmission by the means for signal transmission. The low-noise amplifier may be configured to amplify a signal received from the means for signal transmission for reception by the means for signal processing.

In yet another aspect, the present disclosure provides yet another apparatus for wireless communication. The apparatus includes an integrated circuit, a plurality of antennas, and a module located adjacent to each of the plurality of antennas. Each module includes at least one of a power amplifier or a low-noise amplifier. The power amplifier may be configured to amplify a signal received from the integrated circuit for transmission by at least one of the plurality of antennas. The low-noise amplifier may be configured to amplify a signal received from at least one of the plurality of antennas for reception by the integrated circuit.

In a further aspect, the present disclosure provides a method of manufacturing an apparatus. The method includes providing an integrated circuit, providing an antenna, and providing a module adjacent to the antenna. The module includes at least one of a power amplifier or a low-noise amplifier. The power amplifier may be configured to amplify a signal received from the integrated circuit. The low-noise amplifier may be configured to amplify a signal received from the antenna for reception by the integrated circuit.

These and other aspects of the invention will become more fully understood upon a review of the detailed description, which follows. Other aspects, features, and embodiments of the present disclosure will become apparent to those of ordinary skill in the art, upon reviewing the following description of specific, exemplary embodiments of the present disclosure in conjunction with the accompanying figures. While features of the present disclosure may be discussed relative to certain embodiments and figures below, all embodiments of the present disclosure can include one or more of the advantageous features discussed herein. In other words, while one or more embodiments may be discussed as having certain advantageous features, one or more of such features may also be used in accordance with the various embodiments of the disclosure discussed herein. In similar fashion, while exemplary embodiments may be discussed below as device, system, or method embodiments it should be understood that such exemplary embodiments can be implemented in various devices, systems, and methods.

### BRIEF DESCRIPTION OF THE DRAWINGS

FIG. 1 is a diagram illustrating a side view of an example of a first apparatus according to various aspects of the present disclosure.

FIG. 2 is a diagram illustrating a top view of the example of the first apparatus according to various aspects of the present disclosure.

FIG. 3 is a diagram illustrating a top view of an example of a second apparatus with single feed lines according to various aspects of the present disclosure.

FIG. 4 is a diagram illustrating a top view of an example of the second apparatus with differential feed lines according to various aspects of the present disclosure.

FIG. 5 is a diagram illustrating an example of a first module that may be included in the second apparatus in accordance with various aspects of the present disclosure.

FIG. 6 illustrates an example of a second module that may be included in the second apparatus in accordance with various aspects of the present disclosure.

FIG. 7 are graphs illustrating examples of control schemes applicable to the first module and/or the second module.

FIG. 8 are graphs illustrating additional examples of control schemes applicable to the first module and/or the second module.

FIG. 9 is a diagram illustrating various methods and/or processes for manufacturing the second apparatus according to various aspects of the present disclosure.

### DETAILED DESCRIPTION OF SOME EMBODIMENTS

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Some or all of the aspects of the present disclosure may be implemented in any suitable network or technology.

As mentioned above, components of a mobile device may sometimes produce heat during signal amplification. In some circumstances, heat may not sufficiently dissipate away from the heat source, thereby resulting in hot/heat spots. These hot/heat spots can result in performance degradation and/or component failure, which can adversely impact the user experience. After the signal is amplified, the signal may propagate through various feed lines before reaching an antenna. As the amplified signal propagates through such feed lines, the amplified signal can experience path loss, which generally refers to the attenuation of power of an electromagnetic wave as it propagates through a medium. In order to maintain the same output power level at the antenna, the amount of power consumed to amplify the signal is typically proportional to the path loss of the amplified signal. Accordingly, a reduction in path loss can reduce power consumption by the power amplifier and, thus, the mobile device. Accordingly, enhancements pertaining to heat management and path loss minimization can improve performance of the mobile device and the overall user experience.

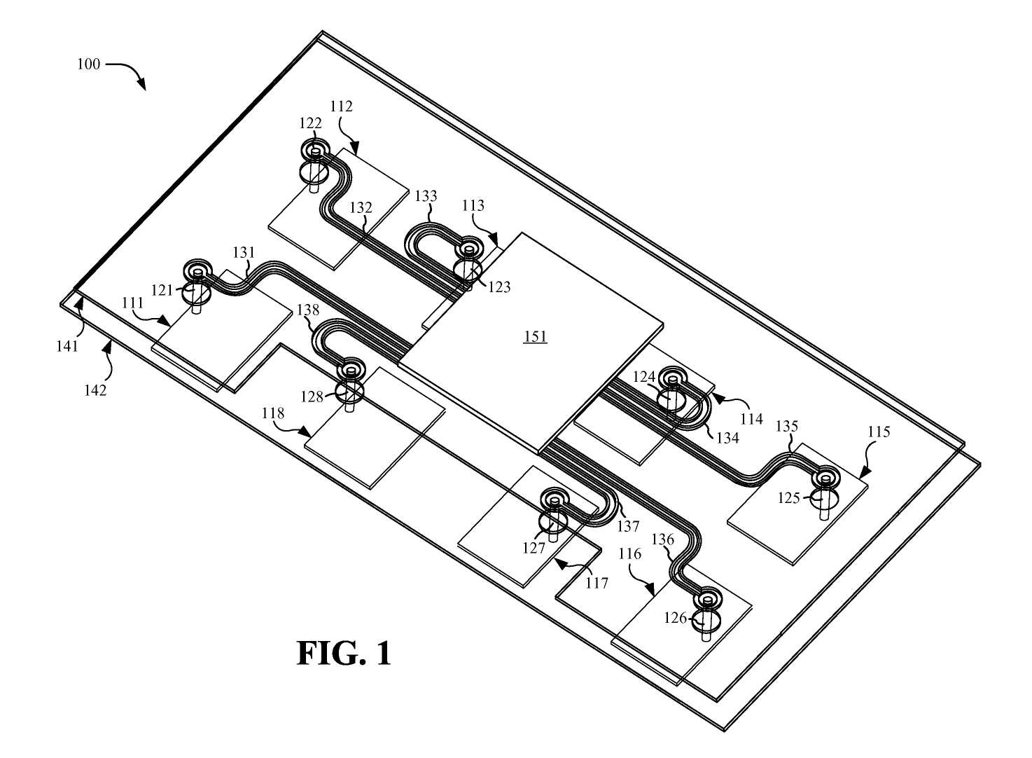

FIG. 1 is a diagram illustrating a side view of an example of an apparatus 100 according to various aspects of the present disclosure. The apparatus 100 may be included as a part of a mobile device, such as a mobile phone, a smartphone, a wearable electronic device, a tablet computer, a laptop computer, and/or any other suitable device. In some configurations, the mobile device may utilize a portion of the frequency spectrum from approximately 10 GHz to approximately 300 GHz for wireless communication.

The apparatus 100 may include one or more antennas. One of ordinary skill in the art will understand that any one or more of the antennas of the apparatus 100 may be arranged in various configurations and/or arrangements without deviating from the scope of the present disclosure. For example, the antennas may be arrayed in various spatial arrangements at the outer perimeter of the apparatus 100 and/or in various spatial arrangements at the internal portions of the apparatus 100 without deviating from the scope of the present disclosure. Also, the apparatus 100 may include many types of antenna without deviating from the scope of the present disclosure. Non-limiting examples of such antenna types include patch antennas, dipole antennas, spiral antennas, and various other types of suitable antennas that will be readily known to one of ordinary skill in the art. By way of example and not limitation, a dipole antenna may include two inductive metals that are bilaterally symmetrical. For example, two straight metal wires may be oriented end-to-end on the same axis. In the non-limiting example illustrated in FIG. 1, the apparatus 100 includes various patch antennas (e.g., antennas 111-118). In some non-limiting examples, the patch antennas may each include a flat, rectangular sheet of metal mounted over a larger sheet of metal called a ground plane. However, as discussed above, one of ordinary skill in the art will understand that the apparatus 100 may additionally or alternatively include various other antennas of similar or different type(s) in various configurations and/or arrangements without deviating from the scope of the present disclosure. In some configurations, one of the antennas 111-118 may provide a first means for signal transmission, and another one of the antennas 111-118 may provide a second means for signal transmission.

The antennas 111-118 may each be connected to their own feed line. In the example illustrated in FIG. 1, the antennas 111-118 are respectively connected to feed lines 131-138. The feed lines 131-138 provide a path of communication between the antennas 111-118, respectively, and the integrated circuit 151. In other words, the feed lines 131-138 provide a path for signals to propagate between the antennas 111-118, respectively, and the integrated circuit 151. For example, a signal originating at the integrated circuit 151 may propagate through the feed line 131 to reach the antenna 111, which may transmit that signal over the air. As another example, a signal received at the antenna 111 may propagate through the feed line 131 to reach the integrated circuit 151. In some configurations, the integrated circuit 151 provides the means for signal processing.

In some configurations, the antennas 111-118 may be located on a layer different from a layer on which the integrated circuit 151 is located. For example, the integrated circuit 151 may be located on a first layer 141, and the antennas 111-118 may be located on a second layer 142. One or more electrical connections may traverse one or more layers of the apparatus 100 to provide pathways of electrical connectivity. One of ordinary skill in the art will understand that various types of electrical connections may be implemented without deviating from the scope of the present disclosure. In some examples, an electrical connection may include a via. Generally, a via is a conductor (e.g., metal conductor) that provides an electrical connection between two or more layers in an electronic circuit. The via may traverse the plane of one or more adjacent layers. Although FIG. 1 provides an illustration of various vias 121-128, one of ordinary skill in the art will understand that the vias 121-128 are non-limiting examples of electrical connections and additional or alternative types of electrical connections may be implemented without deviating from the scope of the present disclosure. In the example illustrated in FIG. 1, the vias 121-128 traverse a first layer 141 to respectively provide connectivity between the feed lines 131-138 (located on the first layer 141) and the antennas 111-118 (located on a second layer 142). In other words, the combination of the feed lines 131-138 and their respective vias 121-128 provide a connection between the respective antennas 111-118 and the integrated circuit 151. For example, a signal originating at the integrated circuit 151 may propagate through the feed line 131 and corresponding via 121 to reach the antenna 111, which may transmit that signal over the air. As another example, a signal received at the antenna 111 may propagate through the via 121 and corresponding feed line 131 to reach the integrated circuit 151. Although vias 121-128 are illustrated in FIG. 1, one of ordinary skill in the art will understand that the vias 121-128 are not a limitation of the present disclosure and alternative embodiments without the vias 121-128 are within the scope of the present disclosure.

The integrated circuit 151 includes various electronic circuits on a semiconductor material (e.g., silicon). In some configurations, the integrated circuit 151 may be a radio frequency integrated circuit (RFIC). One of ordinary skill in the art will appreciate that the integrated circuit 151 may include various types of integrated circuits, each configured for various purposes, without deviating from the scope of the present disclosure. The integrated circuit 151 may be configured to receive signals received at one or more of the antennas 111-118 of the apparatus 100. The integrated circuit 151 may include a low-noise amplifier. With regard to FIG. 1, the low-noise amplifier is an integrated component of (e.g., not separate from) the integrated circuit 151. The low-noise amplifier may be utilized to amplify possibly weak signals. The low-noise amplifier may be configured to boost the signal power while adding as little noise and/or distortion as possible. After the signals received at the antennas 111-118 are amplified by the low-noise amplifier, the amplified signals may be provided to other components (e.g., the integrated circuit 151).

The integrated circuit 151 may also be configured to generate a signal for transmission by one or more of the antennas 111-118 of the apparatus 100. To generate such a signal, the integrated circuit 151 may include a power amplifier. With regard to FIG. 1, the power amplifier is an integrated component of (e.g., not separate from) the integrated circuit 151. The power amplifier may be configured to convert low-power radio-frequency signals into a signal having substantial power in order to drive one or more of the antennas 111-118 of the apparatus 100. Operation of the power amplifier can generate heat. If the integrated circuit 151 includes the power amplifier(s) for all of the antennas 111-118, then the heat generated from the amplification of the signals propagated to all of the antennas 111-118 is concentrated in the area on and/or near the location of the power amplifier(s) of the integrated circuit 151. In some circumstances, heat may not sufficiently dissipate away from the heat source (e.g., the power amplifier in the integrated circuit 151), thereby resulting in hot/heat spots. Hot/heat spots can result in a degradation of the performance of the integrated circuit 151 and/or a failure of one or more components near that hot/heat spot. Accordingly, the accumulation of heat to an extent that exceeds the extent to which heat is dissipated may adverse impact the overall user experience. Conversely, the dissipation of heat to an extent that exceeds the extent to which heat accumulates may obviate some of these adverse effects.

After the power amplifier amplifies the signal, the signal will propagate through the feed lines 131-138 and, if applicable, the vias 121-128, before reaching the antennas 111-118. As the signal propagates through these components, some of the signal power may be attenuated as a result of path loss. Path loss generally refers to the reduction of power of an electromagnetic wave as it propagates through a medium. Therefore, as the generated signal travels through the various feed lines 131-138 and, if applicable, the vias 121-128, the generated signal loses some of its power prior to reaching the antennas 111-118. The apparatus 100 may need to accommodate for this path loss when amplifying the signal using the power amplifier. For example, if the desired signal power at the antenna 111 is x dB and the path loss of the feed line 131 is v dB, then the integrated circuit 151 may need to increase the power used by the power amplifier such that the amplified signal output by the integrated circuit 151 is at least (x+y) dB. Accordingly, the path loss of a propagating signal affects the power consumption of the power amplifier, which thereby also affects heat production. Similarly, a reduction in the path loss can reduce power consumption by the power amplifier, which thereby also reduces heat production.

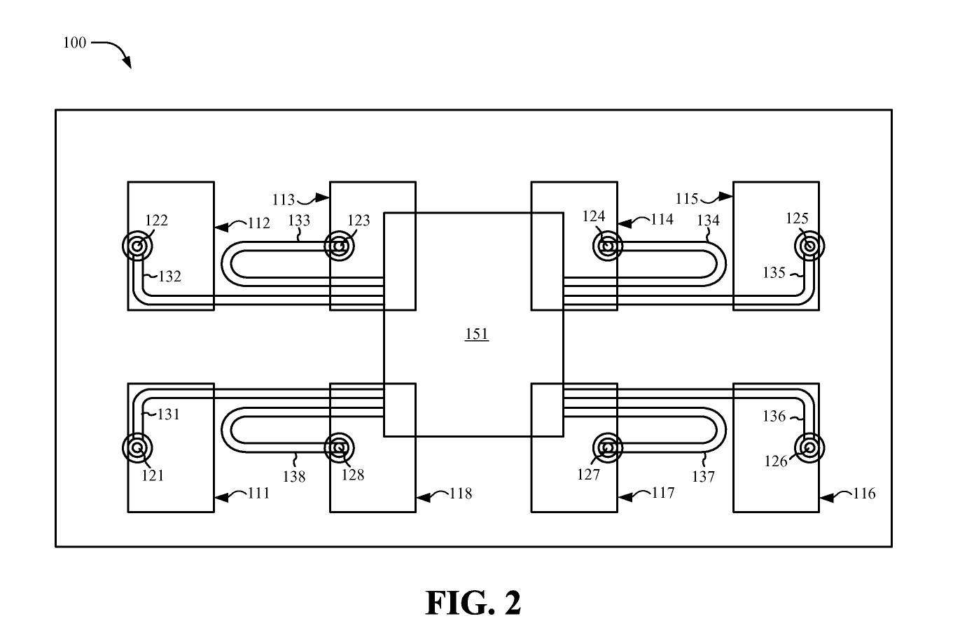

FIG. 2 is a diagram illustrating a top view of the example of the apparatus 100 according to various aspects of the present disclosure. Various aspects illustrated in FIG. 2 are described above with reference to FIG. 1 and therefore will not be repeated.

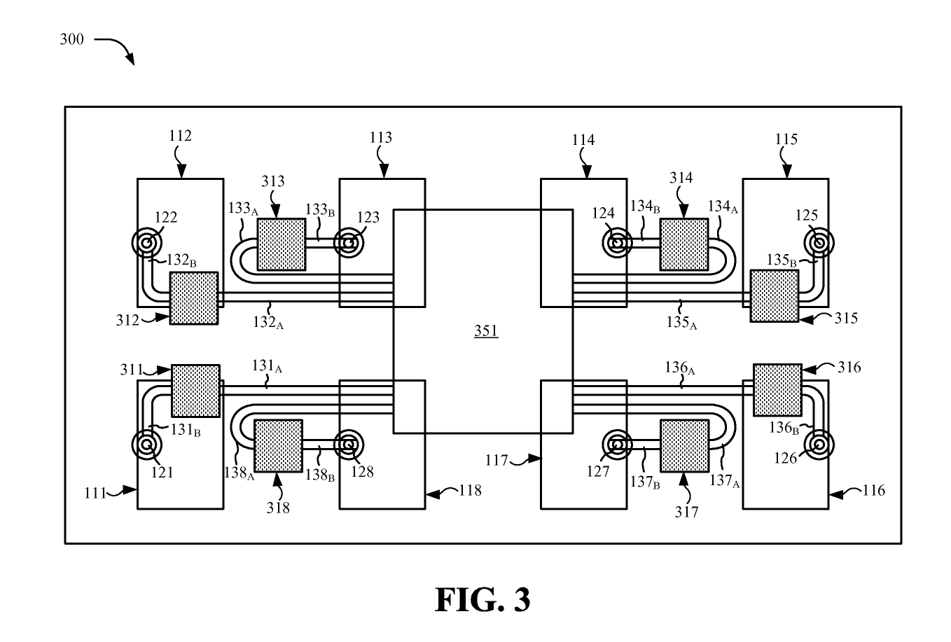

FIG. 3 is a diagram illustrating a top view of an example of another apparatus 300 according to various aspects of the present disclosure. The apparatus 300 may be included as a part of a mobile device, such as a mobile phone, a smartphone, a wearable electronic device, a tablet computer, a laptop computer, and/or any other suitable device. In some configurations, the mobile device may utilize a portion of the frequency spectrum from approximately 10 GHz to approximately 300 GHz for wireless communication. Various aspects illustrated in FIG. 3 are described above with reference to FIG. 1 and therefore will not be repeated. The apparatus 300 illustrated in FIG. 3 includes one or more modules 311-318 located adjacent to a corresponding antenna 111-118, respectively. For example, a module 311 is located adjacent to an antenna 111. The term ‘adjacent’ as used herein may refer to the property of being adjoining, bordering, abutting, proximal, bordering, contiguous, near, nearby, neighboring, and/or close without deviating from the scope of the present disclosure. However, the term ‘adjacent’ shall not be construed as being limited to the example illustrated in FIG. 3. In other words, although the example illustrated in FIG. 3 shows that each of the modules 311-318 are located within particular distances of at least one of the antennas 111-118, respectively, one of ordinary skill in the art will understand that the particular distances depicted in FIG. 3 are merely illustrative and that any one or more of the modules 311-318 may be distanced differently than shown in FIG. 3 without deviating from the scope of the present disclosure. For example, in some configurations, the length of the respective feed lines 131_{B}-138_{B} connecting the respective antennas 111-118 and the respective modules 311-318 can be any distance less than a length of the respective feed lines 131_{A}-138_{A} connecting the respective modules 311-318 and the integrated circuit 351. In some configurations, the integrated circuit 351 provides the means for signal processing.

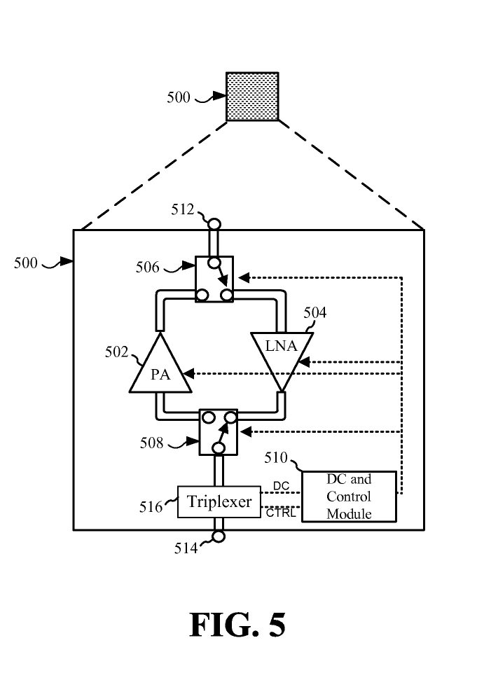

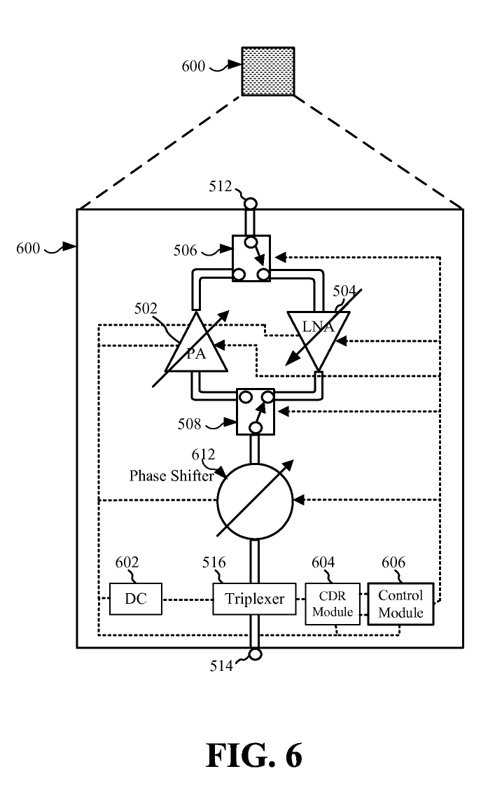

Any one or more of the modules 311-318 may be referred to as a ‘front end (FE) module’ without deviating from the scope of the present disclosure. In some configurations, one of the modules 311-318 may provide a first means for signal control, and another one of the modules 311-318 may provide a second means for signal control. As illustrated in FIG. 3, the modules 311-318 may be separate from (e.g., not an integrated component of) the integrated circuit 351. The modules 311-318 may each include various circuits and/or components without deviating from the scope of the present disclosure. Some non-limiting examples of various circuits and/or component of the modules 311-318 are provided below with reference to FIGS. 5 and 6. As will be described in greater detail below with reference to FIGS. 5 and 6, one or more of the modules 311-318 may include at least one power amplifier. The power amplifier may be configured to convert low-power radio-frequency signals into a signal having substantially greater power in order to drive one or more of the antennas 111-118 of the apparatus 300. In some configurations, each of the modules 311-318 includes a power amplifier configured to amplify signals exclusively for transmission by the respective antenna to which it is adjacent. For example, the module 311 may include a power amplifier that is configured to amplify signals exclusively for transmission by a single antenna 111. In other words, each of the modules 311-318 (each having its own power amplifier) is dedicated to amplifying only the signals destined to the one antenna to which it is adjacent.

Such configurations may provide various advantages with regard to heat management for the apparatus 300. As mentioned above, operation of a power amplifier can generate heat. If heat cannot sufficiently dissipate away from the heat source (e.g., the power amplifier(s)), the levels of accumulated heat can result in performance degradation of the integrated circuit 351 and/or system failure of the overall apparatus 300. Accordingly, the accumulation of heat to an extent that exceeds the extent to which heat is dissipated may adverse impact the overall user experience. In comparison to the apparatus 100 described above with reference to FIGS. 1 and 2, the apparatus 300 illustrated in FIG. 3 may not include the power amplifier for each of the antennas 111-118 as an integrated component of the integrated circuit 351. Accordingly, any heat produced from operation of the power amplifiers of the modules 311-318 is not centralized at the integrated circuit 351. Because any heat produced from operation of the power amplifiers of the modules 311-318 is decentralized away from the integrated circuit 351, the likelihood of hot/heat spots forming from the combination of heat produced from multiple heat sources may be reduced. Furthermore, any heat produced from operation of the power amplifiers of the modules 311-318 is distributed throughout a greater surface area of the apparatus 300, which can improve the rate of heat dissipation away from the apparatus 300. Accordingly, various aspects associated with the example configurations illustrated in FIG. 3 provide certain advantages with regard to heat management for the apparatus 300.

Such configurations may also provide various advantages with regard to power management and path loss minimization. As mentioned above with regard to the apparatus 100 illustrated in FIGS. 1 and 2, after a signal is amplified by a power amplifier, the signal propagates through a feed line before reaching an antenna for transmission. While propagating through the feed line, some of the power of the signal may be attenuated as a result of path loss. Path loss generally refers to the reduction of power of an electromagnetic wave as it propagates through a medium. Because the power amplifier accommodates for this path loss during the amplification process, the path loss of a propagating signal affects the power consumption of the power amplifier. In other words, power consumption by the power amplifier may be directly proportional to the path loss of the signal (after amplification but before reaching the antenna). As also mentioned above, power consumption can affect heat production. Accordingly, a reduction in the path loss can reduce power consumption by the power amplifier, which thereby also reduces heat production. Generally, a power amplifier that maintains the same amount of output signal amplification (and heat production), while simultaneously achieving reduced path loss between the power amplifier and the antenna, will produce a higher signal power for the antennas. In comparison to the apparatus 100 illustrated in FIGS. 1 and 2, the apparatus 300 illustrated in FIG. 3 provides modules 311-318 (which may each include a power amplifier) located adjacent to a respective antenna 111-118. If the modules 311-318 were not located adjacent to the respective antennas 111-118 (e.g., the modules 311-318 were part of the integrated circuit 351), the length of the respective feed lines (e.g., feed lines 131_{B}-138_{B}) between the modules 311-318 and their respective antennas 111-118 would be greater. As the length of the feed lines (e.g., feed lines 131_{B}-138_{B}) increases, the likely amount of path loss (e.g., signal power attenuation) increases. Accordingly, by positioning the modules 311-318 adjacent to the respective antennas 111-118, the likely amount of path loss (e.g., signal power attenuation) is minimized. Accordingly, such configurations may provide various advantages with regard to power management and path loss minimization.

As mentioned above, the configuration illustrated in FIG. 3 is provided for illustrative purposes and alternative configurations are within the scope of the present disclosure. For instance, in some configurations, the distribution of the modules 311-318 throughout the apparatus 300 may be in relation to an amount of heat produced by the respective modules 311-318 during signal amplification. For example, under some circumstances, a first set of one or more modules 311-318 may be distributed as far as possible from a second set of one or more modules 311-318 because the first set of one or more modules 311-318 may produce more heat than the second set of one or more modules 311-318. Such a distribution may improve heat distribution, improve heat dissipation, reduce heat accumulation, and/or reduce the likelihood of hot/heat spot formation.

In other configurations, the distribution of the modules 311-318 throughout the apparatus 300 may be in relation to a rate of dissipation of heat produced by the modules 311-318 during signal amplification. As an example, the modules 311-318 may be distributed such that the distance between adjacent modules 311-318 is approximately equidistant. If the distance between adjacent modules 311-318 is approximately equidistant, a relatively high rate of heat dissipation from those modules 311-318 may be achieved.

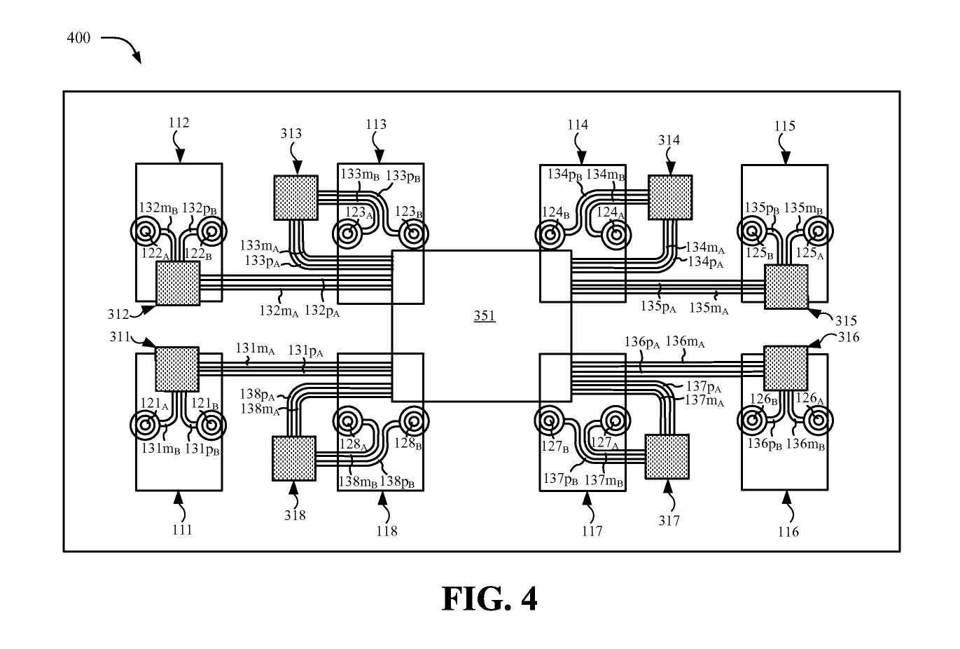

In the non-limiting example illustrated in FIG. 3, the apparatus 300 includes single feed lines 131_{A}-138_{A}, 131_{B}-138_{B}. However, one of ordinary skill in the art will understand that such an apparatus may additionally or alternatively include other types, configurations, and/or arrangements of feed lines without deviating from the scope of the present disclosure. For example, such an apparatus may include two or more feed lines, such as the differential feed lines illustrated in FIG. 4 and described in greater detail below.

FIG. 4 is a diagram illustrating an example of an apparatus 400 with differential feed lines 131m_{A}-138m_{A}, 131m_{B}-138m_{B}, 131p_{A}-138p_{A}, 131p_{B}-138p_{B}. As illustrated in FIG. 4, the integrated circuit 351 is connected to the modules 311-318 by differential feed lines 131m_{A}-138m_{A}, 131p_{A}-138p_{A}, respectively, and the modules 311-318 are connected to the antennas 111-118 by differential feed lines 131m_{B}-138m_{B}, 131p_{B}-138p_{B}, respectively, and, possibly, vias 121_{A}-128_{A}, 121_{B}-128_{B}, respectively. In some circumstances, differential feed lines may be connected to differential antennas (e.g., dipole antennas). Various aspects illustrated in FIG. 4 are described in greater detail above with reference to FIG. 3 and therefore will not be repeated.

FIG. 5 is a diagram illustrating an example of a module 500 that may be included in the apparatus 300, 400. One of ordinary skill in the art will understand that the module 500 illustrated in FIG. 5 may be the same as any one or more of the modules 311-318 described above with reference to FIGS. 3-4. As illustrated in FIG. 5, the module 500 may include a power amplifier 502. The power amplifier 502 may be configured to convert low-power radio-frequency signals into signals having substantial power in order to drive an antenna (e.g., any of the antennas 111-118) for wireless communication. The power amplifier 502 may also have a variable gain control to adjust the amount of amplification applied to low power radio frequency signals. Various aspects of the power amplifier 502 are described above with reference to FIGS. 1-4 and therefore will not be repeated.

The module 500 may also include a low-noise amplifier 504. The low-noise amplifier may be configured to boost the signal power of possibly weak signals received at an antenna (e.g., any of the antennas 111-118). The low-noise amplifier 504 may also have a variable gain control to adjust the amount of amplification provided to the possibly weak signals received at an antenna. After such signals are amplified, the amplified signals may be processed by other components (e.g., the integrated circuit 351). In some configurations, the module 500 may also include a triplexer 516. The triplexer 516 may be a device that implements frequency domain multiplexing. For example, the triplexer 516 may be a three-port to one-port multiplexer. In other words, three ports may be multiplexed onto a fourth port, and the signals on the multiplexed port may occupy disjointed frequency bands such that the signals can coexist on the multiplexed port without substantially interfering with each other.

Although the module 500 illustrated in FIG. 5 is described herein as including various components (e.g., the power amplifier 502, the low-noise amplifier 504, etc.), one of ordinary skill in the art will understand that the module 500 may include fewer than all of the components illustrated in FIG. 5 without deviating from the scope of the present disclosure. For example, in some configurations, the module 500 may include the power amplifier 502 without including the low-noise amplifier 504 (nor one or more of the other components illustrated in FIG. 5). As another example, in some configurations, the module 500 may include the low-noise amplifier 504 without including the power amplifier 502 (nor one or more of the other components illustrated in FIG. 5). One of ordinary skill in the art will understand that various configurations including one or more of such components may be implemented without deviating from the scope of the present disclosure. Furthermore, one of ordinary skill in the art will also understand that the module 500 may include various other components not explicitly illustrated in FIG. 5 without deviating from the scope of the present disclosure.

In some configurations, the module 500 may have a single feed line at a first end 512 of the module 500 and a single feed line at a second end 514 of the module 500. The first end 512 of the module 500 may be communicatively coupled to antenna (e.g., any of the antennas 111-118), and the second end 514 of the module 500 may be communicatively coupled to an integrated circuit (e.g., the integrated circuit 351). Although the module 500 illustrated in FIG. 5 shows single feed lines (e.g., as also illustrated in FIG. 3) at the first end 512 and the second end 514, one of ordinary skill in the art will understand that the module 500 may alternatively or additionally include two (or more) feed lines (e.g., differential feed lines, as illustrated in FIG. 4) at the first end 512 and/or the second end 514 without deviating from the scope of the present disclosure. The module 500 may include a switching mechanism configured to switch operation of the module 500 between transmission and reception. One of ordinary skill in the art will understand that such a switching mechanism may be implemented in various configurations and arrangements without deviating from the scope of the present disclosure. A non-limiting example of such a switching mechanism may include two switches 506, 508 that are each communicatively coupled to the power amplifier 502 and the low-noise amplifier 504. These switches 506, 508 may be configured to switch between transmission (TX) and reception (RX) settings. As such, these switches may sometimes be referred to as “TX/RX switches” or “RX/TX switches.” A direct current (DC) and control module 510 may be configured to control the power amplifier 502, the low-noise amplifier 504, the first switch 506 and/or the second switch 508.

During a reception operation, a signal may be received at the first end 512 of the module 500 (e.g., from any of the antennas 111-118), and the switches 506, 508 may switch to a reception configuration, as illustrated in FIG. 5. That is, the first switch 506 will provide connectivity between the signal received at the first end 512 of the module 500 and the low-noise amplifier 504, and the second switch 508 will provide connectivity between the low-noise amplifier 504 and the second end 514 of the module 500. Accordingly, the signal received at an antenna (e.g., any of the antennas 111-118) is amplified and propagated to other components (e.g., the integrated circuit 351).

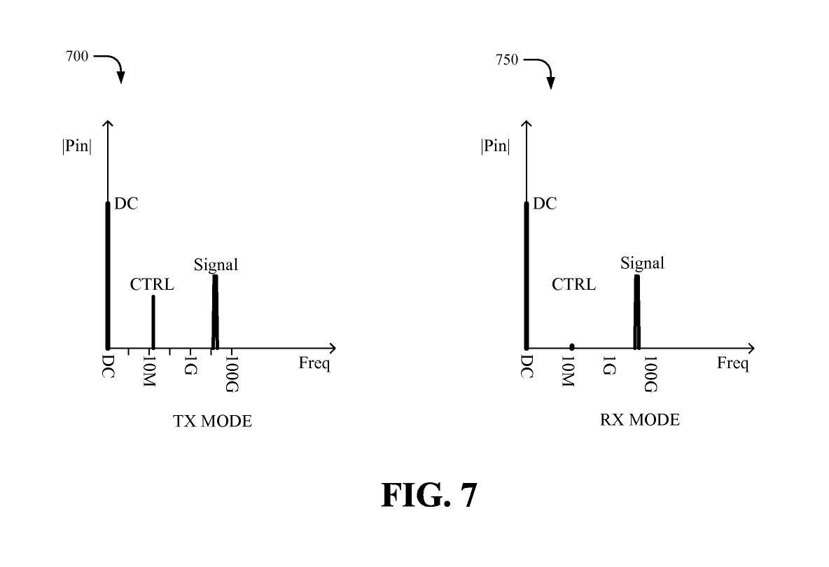

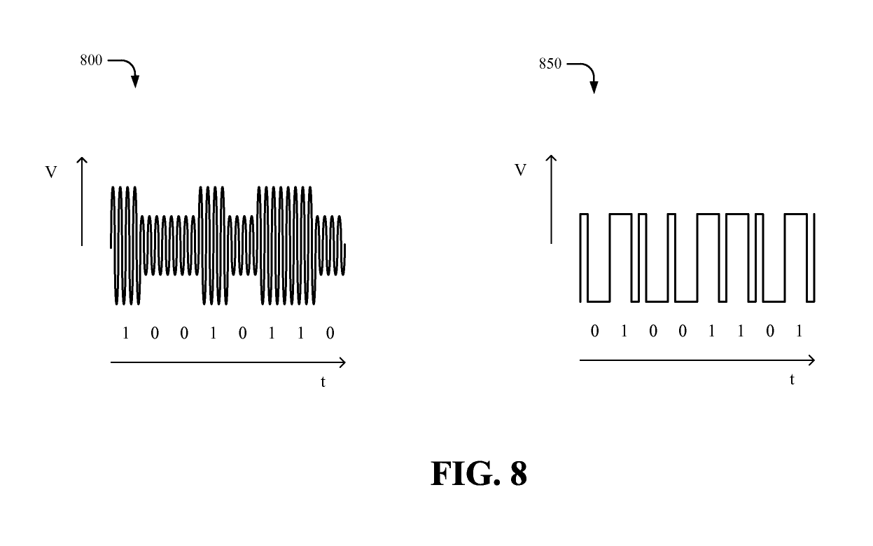

During a transmission operation, a signal may be received at the second end 514 of the module 500 (e.g., from the integrated circuit 351), and the switches 506, 508 may switch to a transmission configuration. That is, the second switch 508 will provide connectivity between the signal received at the second end 514 of the module 500 and the power amplifier 502, and the first switch 506 will provide connectivity between the power amplifier 502 and the first end 512 of the module 500. Accordingly, the signal received from another component (e.g., the integrated circuit 351) is amplified and propagated to an antenna (e.g., any of the antennas 111-118) for transmission. (Various control schemes pertaining to the module 500 are described in greater detail below with reference to FIGS. 7-8 and therefore will not be repeated.)

FIG. 6 is a diagram illustrating an example of a module 600 included in the apparatus 300, 400 in accordance with various aspects of the present disclosure. One of ordinary skill in the art will understand that the module 600 illustrated in FIG. 6 may be the same as any one or more of the modules 311-318 described above with reference to FIGS. 3-4. Various aspects of the power amplifier 502, the low-noise amplifier 504, the switches 506, 508, and/or the triplexer 516 are described above with reference to FIGS. 1-5 and therefore will not be repeated. Although the module 600 illustrated in FIG. 6 shows single feed lines (e.g., as also illustrated in FIG. 3) at the first end 512 and the second end 514, one of ordinary skill in the art will understand that the module 600 may alternatively or additionally include two (or more) feed lines (e.g., differential feed lines, as illustrated in FIG. 4) at the first end 512 and/or the second end 514 without deviating from the scope of the present disclosure.

Although the module 600 illustrated in FIG. 6 is shown as including various components (e.g., the power amplifier 502, the low-noise amplifier 504, etc.), one of ordinary skill in the art will understand that the module 600 may include fewer than all of the components illustrated in FIG. 6 without deviating from the scope of the present disclosure. For example, in some configurations, the module 600 may include the power amplifier 502 without including the low-noise amplifier 504 (nor one or more of the other components illustrated in FIG. 6). As another example, in some configurations, the module 600 may include the low-noise amplifier 504 without including the power amplifier 502 (nor one or more of the other components illustrated in FIG. 6). One of ordinary skill in the art will understand that various configurations including one or more of such components may be implemented without deviating from the scope of the present disclosure. Furthermore, one of ordinary skill in the art will also understand that the module 600 may include various other components not explicitly illustrated in FIG. 6 without deviating from the scope of the present disclosure.

In some configurations, the module 600 may also include a clock and data recovery (CDR) module 604. Some digital data streams (e.g., high-speed serial data streams) may be sent without an accompanying clock signal. The receiver may generate a clock from an approximate frequency reference and then phase-align to the transitions in the data stream with a phase-locked loop. This process may be commonly known as clock and data recovery and may be performed by the CDR module 604. Simpler methods of clock and data recovery which consume less die area and design effort than a full phase-locked loop (PLL) may also be possible, as detailed later in reference to FIG. 8. In some configurations, the module 600 may also include a phase shifter 612. The phase shifter 612 may be configured to shift the phase of signals received at the second end 514 (e.g., from the integrated circuit 351) prior to amplification by the power amplifier 502 during a transmission configuration. The phase shifter 612 may also be configured to shift the phase of signals received at the first end 512, after amplification by the low-noise amplifier 504 during a reception configuration. In some configurations, the power amplifier 502 and low-noise amplifier 504 may have variable gain control which may be coordinated with the phase shifter control. The DC 602 and control module 606 may be configured to control the power amplifier 502, the low-noise amplifier 504, the first switch 506, the second switch 508 and/or the phase shifter 612. (Various control schemes pertaining to the module 600 are described in greater detail below with reference to FIGS. 7-8 and therefore will not be repeated here.)

In comparison to conventional systems, which may include certain components (e.g., the power amplifier 502, the low-noise amplifier 504, the first switch 506, the second switch 508 and/or the phase shifter 612) as an integrated component of the integrated circuit, various aspects of the present disclosure (e.g., aspects pertaining to FIGS. 3-6) do not necessarily require such components (e.g., the power amplifier 502, the low-noise amplifier 504, the first switch 506, the second switch 508 and/or the phase shifter 612) to be an integrated component of the integrated circuit (e.g., the integrated circuit 351). In other words, various aspects of the present disclosure (e.g., aspects pertaining to FIGS. 3-6) may have such components (e.g., the power amplifier 502, the low-noise amplifier 504, the first switch 506, the second switch 508 and/or the phase shifter 612) separate from the integrated circuit (e.g., the integrated circuit 351). Such configurations allow for various advantages over conventional systems.

As an example of an advantage, the integrated circuit 351 of the apparatus 300, 400 illustrated in FIGS. 3-4 can be reduced in size in comparison to integrated circuits in conventional systems, because that integrated circuit 351 does not necessarily need to include the aforementioned components (e.g., the power amplifier 502, the low-noise amplifier 504, the first switch 506, the second switch 508 and/or the phase shifter 612) on the integrated circuit 351. A splitter/combiner network can be included on the main board instead of on the integrated circuit. In other words, the splitter/combiner network may be built on-board instead of on-chip. The foregoing aspects allow the integrated circuit 351 to have a smaller ‘footprint’ (e.g., the amount of space occupied by the integrated circuit 351) on the overall apparatus 300 relative to the footprint of conventional integrated circuits. Because of its relatively smaller footprint, the integrated circuit 351 can fit into smaller areas and allow for more placement options in the overall device into which the apparatus 300, 400 may be included.

As another example of an advantage, the integrated circuit 351 of the apparatus 300, 400 illustrated in FIGS. 3-4 can be placed on the main board instead of the antenna. The main board may be another printed circuit board (PCB) in the mobile device which contains additional integrated circuits such as applications processor, digital baseband modem and circuits to support user interfaces. The main board may be connected to the antenna module by a coaxial cable or through a board-to-board connector. Because the power amplifier 502 is located adjacent to the antenna, concerns associated with path loss in relatively lengthy feed lines of conventional systems are obviated. Accordingly, the length of the feed line between the integrated circuit 351 and the antenna is less of a concern for the configurations described with regard to FIGS. 3-4. As yet another example of an advantage, the antenna(s) and/or module(s) may be split into sub-modules. By splitting these components into sub-modules, each sub-module may fit into smaller areas and allow for more placement options in the overall device into which the apparatus 300, 400 may be included. Also, such configurations may enable beamforming between sub-modules.

As a further example of an advantage, the apparatus 300, 400 has reduced thermal loading of its radio frequency and/or antenna module (e.g., by up to 40% to 100% or more) relative to conventional systems. Also, the apparatus 300, 400 has improved transmission efficiency and reduced power consumption relative to conventional systems. If the apparatus 300, 400 is included in a mobile device (e.g., a mobile phone), the mobile device will benefit from increased talk time and improved battery life relative to conventional systems. Additionally, the apparatus 300, 400 has increased system output power, thereby enabling high throughput in uplink connections, relative to conventional systems. The apparatus 300, 400 also has reduced noise figure and increased sensitivity, thereby enabling high throughput in downlink connections, relative to conventional systems.

FIG. 7 illustrates an example of a control scheme applicable to the modules 500, 600 illustrated in and described above with reference to FIGS. 5-6. A first graph 700 shown in FIG. 7 pertains to the transmission mode of operation. A second graph 750 shown in FIG. 7 pertains to the reception mode of operation. The first and second graphs 700, 750 illustrate relative signal amplitude on the y-axis and relative frequency on the x-axis. The x-axis for both graphs is log scale. DC or zero Hz is represented on the leftmost side of the x-axis. The second end 514 (as illustrated in FIGS. 5-6) may have three signals combined on it. Such signals may include a DC signal, a control signal, and the desired signal that is at a relatively high frequency (e.g., between approximately 10 GHz and approximately 300 GHz). It may be desirable to have simple control circuits to select between configuring the module 500, 600 for transmitting or receiving. One non-limiting example includes a continuous wave (CW) tone placed above DC and well below the relatively high frequency signal. If the CW tone is separated out (e.g., using a triplexer), then a simple envelope detector can detect the amplitude of the control (CTRL) tone, and use of a comparator or 1 bit quantizer can generate a digital signal which selects between transmit and receive configurations. For example, if the CTRL tone amplitude is above a first threshold, the module 500, 600 is configured for transmit, the power amplifier 502 is enabled, the low-noise amplifier 504 is disabled (e.g., to conserve DC power), and the switches 506, 508 are set to transmit (e.g., transmission mode of operation). Conversely, if the CTRL tone amplitude is below a second threshold, the module 500, 600 is configured for receive, the power amplifier 502 is disabled (e.g., to conserve DC power), the low-noise amplifier 504 is enabled, and the switches 506, 508 are set to receive (e.g., reception mode of operation). The first and second thresholds may have different levels or values. For example, first threshold may be higher than the second threshold (e.g., to avoid ambiguity when the CTRL tone amplitude is near one of the two thresholds). It may also be possible to set the module 500, 600 to a power-down state when the CTRL tone is above the second threshold and below the first threshold. In the power-down state, the power amplifier 502 and the low-noise amplifier 504 may be disabled (e.g., to conserve DC power). One or more of the aspects described above with reference to FIG. 7 may be implemented or controlled by the DC and control module 510 illustrated in FIG. 5. In some examples, the DC and control module 510 is the control mechanism of the module 500 illustrated in FIG. 5. The control mechanism (e.g., the DC and control module 510) may be configured to select the operation of the module 500 between the transmission mode and the reception mode in accordance with various aspect described in greater detail above.

FIG. 8 illustrates another example of a control scheme applicable to the aforementioned modules 500, 600 illustrated in and described above with reference to FIGS. 5-6. With regard to the module 600 illustrated in FIG. 6, in addition to selecting between transmission and reception modes of operation, it may be desirable to control phase shift of the phase shifter 612, as described in greater detail above. Phase shift control may be implemented by the phase shifter 612. Generally, phase shift control may refer to a change to the phase of the signal output from the module 600. Additionally, it may be desirable to control output amplitude of the power amplifier 502 and/or the low-noise amplifier 504. Generally, output amplitude control may refer to the gain and/or attenuation of an output signal. Accordingly, output amplitude control of the power amplifier 502 and/or low-noise amplifier 504 may refer to any increase (e.g., gain) and/or decrease (e.g., attenuation) of the signal power that is output by the power amplifier 502 and/or low-noise amplifier 504. One or more of the aspects described herein with reference to FIG. 8 may be implemented or controlled by the control module 606 illustrated in FIG. 6. In some examples, the control module 606 is the control mechanism of the module 600 illustrated in FIG. 6. The control mechanism (e.g., the control module 606) may be configured to control the amplitude of a signal output by the module 600 in accordance to various aspects of the present disclosure. The control mechanism (e.g., the control module 606) may also be configured to control the phase shift of a signal output by the module 600 in accordance to various aspects of the present disclosure.

In some configurations, a control signal and a high frequency signal (e.g., between approximately 10 GHz and approximately 300 GHz) may be separated out (e.g., using a triplexer). Some signals higher than the control signal frequency yet lower than a 10 GHz signal may also be separated using standard triplexers. As illustrated in FIG. 6, DC power may be provided to the power amplifier 502, the low-noise amplifier 504, the switches 506, 508, and/or the phase shifter 612. The control signal may be routed to the CDR module 604, and the output clock and data may be connected to the control module 606. The control module 606 may contain registers that are programmed to select between transmit and receive configurations, select phase shift of variable phase shifter and gain or attenuation of the phase shifter 612, power amplifier 502 and/or low-noise amplifier 504. Many examples of two-wire digital control interfaces are known to one ordinary skill in the art. Non-limiting examples include MIPI RFFE, 12C, and various other company-specific proprietary protocols. It may be desirable for the CDR module 604 to be relatively simple in order to conserve module die area and reduce module design complexity.

Two non-limiting examples of control schemes are shown in the graphs 800, 850 illustrated in FIG. 8. As illustrated in the graphs 800, 850, the amplitude is represented on the y-axis labeled “V” and time is represented on the x-axis labeled “t.” In the graph 800 illustrated on the left-hand side of FIG. 8, a control signal may be amplitude-modulated. The amplitude-modulated control signal may be split and applied to an envelope detector and a limiting amplifier. The output of the limiting amplifier may be a clock signal and the output of the envelope detector may be a data signal. In the graph 800 illustrated on the left-hand side of FIG. 8, there are four cycles of the control signal for each data bit, as labeled along the x-axis. A relatively small amount of additional digital processing may be required to align the phase and frequency of the clock and data signal. The graph 850 illustrated on the right-hand side of FIG. 8 shows another example of a control scheme. In this example, short pulses may be used to indicate a low data bit of “0” and long pulses to indicate a high data bit of “1.” Rising edges may be recovered as a clock signal, and the delay between rising and falling edge may indicate a data bit. One of ordinary skill in the art will understand that additional and alternative control schemes exist and are within the scope of the present disclosure. For instance, any of the example control schemes illustrated in FIG. 8 may be implemented with a very low frequency signal (e.g., less than 1 MHz) and combined with any of the example control schemes illustrated in FIG. 7 to provide fast switching between transmission and reception modes of operation while allowing amplitude control and/or phase-shift control of the signal output from the module 500, 600. If differential feed lines are utilized (e.g., as described above with reference to FIG. 4), the clock signal may be added to one of the differential feed lines and the data signal may be added to the other differential feed line. Using dual triplexers, clock and data signals may be extracted from differential feed lines with minimal signal conditioning and, possibly, without a CDR circuit.

One of ordinary skill in the art will understand that the description provided herein with reference to FIGS. 5-8 illustrate non-limiting examples circuit components and control schemes that may be implemented in various aspects of the present disclosure. Accordingly, one of ordinary skill in the art will appreciate that various other circuit components and/or control schemes may be implemented without deviating from the scope of the present disclosure.

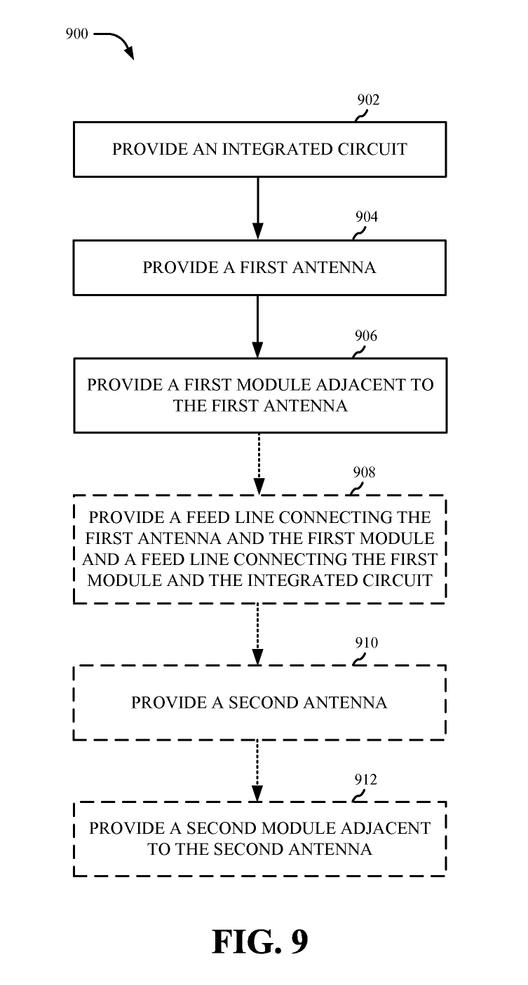

FIG. 9 illustrates an exemplary flow diagram of exemplary methods for manufacturing the apparatus 300, 400 according to various aspects of the present disclosure. One of ordinary skill in the art will understand that the order of some of the blocks illustrated in FIG. 9 may be changed without deviating from the scope of the present disclosure. One of ordinary skill in the art will also understand that any one or more of the blocks illustrated in FIG. 9 may be combined without deviating from the scope of the present disclosure. Optional blocks are illustrated in dashed lines. The exemplary methods described herein may be performed by various types of fabrication devices utilizing various techniques without deviating from the scope of the present disclosure. Certain portions of the description provided below may mention a fabrication device. Generally, the term ‘fabrication device’ refers to any apparatus, or any plurality of apparatuses, that is/are configured for the manufacture, fabrication, and/or packaging of printed circuit boards (PCBs), integrated circuits (ICs), electrical circuits, semiconductors, microchips, and/or other suitable apparatuses, such as the apparatus 300, 400 described in greater detail herein. The fabrication device may implement various techniques without deviating from the scope of the present disclosure. Non-limiting examples of such techniques may include doping, etching, packaging, and/or various other suitable processes that may be applied to one or more layers of conductive materials, semi-conductive materials, and/or insulative materials. Even though the description provided herein with reference to a method and/or process of manufacturing may utilize the term ‘providing,’ one of ordinary skill in the art will understand that ‘providing’ may refer to fabricating, constructing, manufacturing, assembling, composing, creating, etching, forming, making, preparing, producing, tooling, and various other suitable terms without deviating from the scope of the present disclosure.

FIG. 9 includes a diagram 900 illustrating examples of various methods and/or processes for manufacturing an apparatus (e.g., the apparatus 300, 400 described above and illustrated in FIGS. 3-4) utilizing a fabrication device. At block 902, the fabrication device may provide an integrated circuit, such as the integrated circuit 351 described above and illustrated in FIGS. 3-4. At block 904, the fabrication device may provide a first antenna, such as any of the antennas 111-118 described above and illustrated in FIGS. 3-4. At block 906, the fabrication device may provide a first module adjacent to the first antenna, such as any of the module 311-318 described above and illustrated in FIGS. 3-4. The first module may include at least one of a power amplifier (e.g., the power amplifier 502 described above and illustrated in FIGS. 5-6) or a low-noise amplifier (e.g., the low-noise amplifier 504 described above and illustrated in FIGS. 5-6). The power amplifier 502 may be configured to amplify a signal received from the integrated circuit. The low-noise amplifier may be configured to amplify a signal received from the antennas for reception by the integrated circuit.

In some configurations, the fabrication device may provide the first module at a location that is separate from a location of the integrated circuit. For example, referring to FIGS. 3-4, the fabrication device may provide any of the modules 311-318 at locations that are separate from the location of the integrated circuit 351.

In some configurations, providing the first module by the fabrication device may include providing a switching mechanism configured to switch operation of the first module between a transmission mode and a reception mode. For example, referring to FIGS. 5-6, the switching mechanism may include two switches 506, 508. However, as mentioned above, this is a non-limiting example of such a switching mechanism and various other switching mechanisms exist and are within the scope of the present disclosure. For instance, some non-limiting examples of such other switching mechanisms are provided in U.S. Patent Application Publication Number 2014/0152385, currently issued as U.S. Pat. No. 9,026,060, the contents of which are hereby expressly incorporated by reference.

In some configurations, providing the first module by the fabrication device may include providing a phase shifter, such as the phase shifter 612 described above and illustrated in FIG. 6. The phase shifter may be configured to shift a phase of the signal received from the integrated circuit prior to amplification.

In some configurations, providing the first module by the fabrication device may include providing a control mechanism, such as the DC and control module 510 described above and illustrated in FIG. 5 and/or the control module 606 described above and illustrated in FIG. 6. The control mechanism may be configured to select the operation of the first module between a transmission mode and a reception mode. In some configurations, the control mechanism may utilize various control schemes described above and illustrated in FIGS. 7-8.

At block 908, the fabrication device may provide a feed line connecting the first antenna and the first module and a feed line connecting the first module and the integrated circuit. The length of the feed line connecting the first antenna and the first module is less than the length of the feed line connecting the first module and the integrated circuit. For example, referring to FIG. 3, the length of the respective feed lines 131_{B}-138_{B} connecting the respective antennas 111-118 and the respective modules 311-318 may be less than the length of the respective feed lines 131_{A}-138_{A} connecting the respective modules 311-318 and the integrated circuit 351.

At block 910, the fabrication device may provide a second antenna, such as another one of the antennas 111-118 described above and illustrated in FIGS. 3-4. At block 912, the fabrication device may provide a second module adjacent to the second antenna, such as another one of the module 311-318 described above and illustrated in FIGS. 3-4. The second module may include at least one of a power amplifier (e.g., the power amplifier 502 described above and illustrated in FIGS. 5-6) or a low-noise amplifier (e.g., the low-noise amplifier 504 described above and illustrated in FIGS. 5-6). In some configurations, the first and second antennas and the first and second modules may be provided on a common substrate.

Generally, the term ‘substrate’ may refer to a solid substance onto which a layer of another substance is applied and to which that other substance adheres. In some examples, the substrate is the material on which the one or more layers 141, 142 of the apparatus 100, 300, 400 are applied. Some example materials are FR-4, Megtron 6 and/or Rogers Duroid. In some examples, the substrate may refer to a thin slice of material, such as silicon, silicon dioxide, aluminum oxide, sapphire, germanium, gallium arsenide, an alloy of silicon and germanium, and/or indium phosphide. One of ordinary skill in the art will understand that alternative terms (e.g., wafer, etc.) may be used to describe the aforementioned ‘substrate’ without deviating from the scope of the present disclosure. Generally, the term ‘common’ may be characterized as two (or more) things that belong to or share a feature or aspect. For example, two (or more) antennas and/or two (or more) modules may share a common substrate when those two (or more) antennas and/or two (or more) modules belong, share, are built on, or are provided on the same substrate (e.g., wafer).

The methods and/or processes described with reference to FIG. 9 are provided for illustrative purposes and are not intended to limit the scope of the present disclosure. The methods and/or processes described with reference to FIG. 9 may be performed in sequences different from those illustrated therein without deviating from the scope of the present disclosure. Additionally, some or all of the methods and/or processes described with reference to FIG. 9 may be performed individually and/or together without deviating from the scope of the present disclosure. It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

One of ordinary skill in the art will understand that various aspects described throughout the present disclosure may be extended to many telecommunication systems, network architectures and communication standards, including a 5G system or any other suitable system defined by 3GPP or other standards body, without deviating from the scope of the present disclosure. The actual telecommunication standard, network architecture, and/or communication standard employed may depend on the specific application and the overall design constraints imposed on the system.

One of ordinary skill in the art will also understand that the various apparatuses described herein (e.g., apparatus 100, 300, 400) may include alternative and/or additional elements without deviating from the scope of the present disclosure. In accordance with various aspects of the present disclosure, such apparatus may also include a processing system (not shown) that includes one or more processors. In some configurations, these one or more processors provide the means for signal processing. Examples of the one or more processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. The processing system may be implemented with a bus. The bus may include any number of interconnecting buses and bridges depending on the specific application of the processing system and the overall design constraints. The bus may link together various circuits including the one or more processors, a memory, and a computer-readable media. The bus may also link various other circuits such as timing sources, peripherals, voltage regulators, and power management circuits, which are well known in the art. The one or more processors may be responsible for managing the bus and general processing, including the execution of software stored on the computer-readable medium. The software, when executed by the one or more processors, causes the processing system to perform the various functions described below for any one or more apparatuses. The computer-readable medium may be used for storing data that is manipulated by the one or more processors when executing software. Those skilled in the art will recognize how best to implement the described functionality presented throughout this disclosure depending on the particular application and the overall design constraints imposed on the overall system.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

The previous description is provided to enable any person skilled in the art to practice some aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of some aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f), unless the element is expressly recited using the phrase “means for” or, in the case of a method claim, the element is recited using the phrase “step for.”

1. An apparatus for wireless communication, the apparatus comprising:
an integrated circuit;
a first antenna;
a first module located adjacent to the first antenna, the first module comprising at least one of:
a first power amplifier configured to amplify a first signal received from the integrated circuit for transmission by the first antenna; or
a first low-noise amplifier configured to amplify a signal received from the first antenna for reception by the integrated circuit;
a second antenna, and
a second module located adjacent to the second antenna, the second module comprising at least one of:
a second power amplifier configured to amplify a second signal received from the integrated circuit for transmission by the second antenna; or
a second low-noise amplifier configured to amplify a signal received from the second antenna for reception by the integrated circuit,
wherein a distribution of the first and second modules throughout the apparatus is in relation to an amount of heat produced by the first module during amplification of the first signal and an amount of heat produced by the second module during amplification of the second signal.

2. The apparatus of claim 1, wherein the first module is separate from the integrated circuit.

3. The apparatus of claim 1, wherein a length of a feed line connecting the first antenna and the first module is less than a length of a feed line connecting the first module and the integrated circuit.

4. The apparatus of claim 1, wherein the first power amplifier of the first module is further configured to amplify signals exclusively for transmission by the first antenna.

5. The apparatus of claim 1, wherein the first module includes the first power amplifier and the first low-noise amplifier and further comprises:
a switching mechanism configured to switch operation of the first module between a transmission mode and a reception mode.

6. The apparatus of claim 5, wherein the first module further comprises:
a control mechanism configured to select the operation of the first module between the transmission mode and the reception mode.

7. The apparatus of claim 5, wherein the first module further comprises:
a control mechanism configured to control an amplitude of a signal output by the first module.

8. The apparatus of claim 5, wherein the first module further comprises:
a phase shifter configured to at least one of:
shift a phase of the first signal received from the integrated circuit prior to amplification by the first power amplifier; or
shift a phase of the signal received from the first antenna for transmission to the integrated circuit.

9. The apparatus of claim 8, wherein the first module further comprises:
a control mechanism configured to control a phase shift of a signal output by the first module.

10. (canceled)

11. The apparatus of claim 1, wherein the first and second antennas and the first and second modules are located on a common substrate.

12. (canceled)

13. The apparatus of claim 1, wherein a distribution of the first and second modules throughout the apparatus is alternatively in relation to a rate of dissipation of heat produced by the first module during amplification of the first signal and heat produced by the second module during amplification of the second signal.

14. An apparatus for wireless communication, the apparatus comprising:
means for signal processing;
first means for signal transmission;
first means for signal control located adjacent to the first means for signal transmission, the first means for signal control comprising at least one of:
a first power amplifier configured to amplify a first signal received from the means for signal processing for transmission by the first means for signal transmission; or
a first low-noise amplifier configured to amplify a signal received from the first means for signal transmission for reception by the means for signal processing;
a second means for signal transmission; and
a second means for signal control located adjacent to the second means for signal transmission, the second means for signal control comprising at least one of:
a second power amplifier configured to amplify a second signal received from the means for signal processing for transmission by the second means for signal transmission, or
a second low-noise amplifier configured to amplify a signal received from the second means for signal transmission for reception by the means for signal processing,
wherein a distribution of the first and second means for signal control throughout the apparatus is in relation to an amount of heat produced by the first means for signal control during amplification of the first signal and an amount of heat produced by the second means for signal control during amplification of the second signal.

15. The apparatus of claim 14, wherein the first means for signal control is separate from the means for signal processing.

16. The apparatus of claim 14, wherein a length of a feed line connecting the first means for signal transmission and the first means for signal control is less than a length of a feed line connecting the first means for signal control and the means for signal processing.

17. The apparatus of claim 14, wherein the first power amplifier of the first means for signal control is further configured to amplify signals exclusively for transmission by the first means for transmission.

18. The apparatus of claim 14, wherein the first means for signal control includes the first power amplifier and the first low-noise amplifier and further comprises:
a switching mechanism configured to switch operation of the first means for signal control between a transmission mode and a reception mode.

19. The apparatus of claim 18, wherein the first means for signal control further comprises:
a control mechanism configured to select the operation of the first means for signal control between the transmission mode and the reception mode.

20. The apparatus of claim 18, wherein the first means for signal control further comprises:
a control mechanism configured to control amplitude of a signal output by the first means for signal control.

21. The apparatus of claim 18, wherein the first means for signal control further comprises:
a phase shifter configured to at least one of:
shift a phase of the first signal received from the means for signal processing prior to amplification by the first power amplifier; or
shift a phase of the signal received from the first means for signal transmission for transmission to the means for signal processing.

22. The apparatus of claim 21, wherein the first means for signal control further comprises:
a control mechanism configured to control a phase shift of a signal output by the first means for signal control.

23. (canceled)

24. The apparatus of claim 14, wherein the first and second means for signal transmission and the first and second means for signal control are located on a common substrate.

25. (canceled)

26. The apparatus of claim 14, wherein a distribution of the first and second means for signal control throughout the apparatus is alternatively in relation to a rate of dissipation of heat produced by the first means for signal control during amplification of the first signal and heat produced by the second means for signal control during amplification of the second signal.

27. An apparatus for wireless communication, the apparatus comprising:
an integrated circuit;
a plurality of antennas;
a plurality of modules, each module located adjacent to each of the plurality of antennas, wherein each module comprises at least one of:
a power amplifier configured to amplify a signal received from the integrated circuit for transmission by at least one of the plurality of antennas; or
a low-noise amplifier configured to amplify a signal received from at least one of the plurality of antennas for reception by the integrated circuit,
wherein a distribution of the plurality of modules throughout the apparatus is in relation to an amount of heat produced by each module during amplification of the signal.

28. The apparatus of claim 27, wherein each module is separate from the integrated circuit.

29. The apparatus of claim 27, wherein the plurality of antennas and each module are located on a common substrate.

30. The apparatus of claim 27, wherein each module includes the power amplifier and the low-noise amplifier and further comprises:
a switching mechanism configured to switch operation of the module between a transmission mode and a reception mode; and
a control mechanism configured to select the operation of the module between the transmission mode and the reception mode.

31. The apparatus of claim 30, wherein each module further comprises:
a phase shifter configured to at least one of:
shift a phase of the signal received from the integrated circuit prior to amplification; or
shift a phase of the signal received from at least one of the plurality of antennas for transmission to the integrated circuit.

32. The apparatus of claim 31, wherein the control mechanism is further configured to at least one of control amplitude or phase shift of a signal output by the module.

33. A method of manufacturing an apparatus, the method comprising:
providing an integrated circuit;
providing a first antenna;
providing a first module located adjacent to the first antenna, wherein the first module comprises at least one of:
a first power amplifier configured to amplify a first signal received from the integrated circuit for transmission by the first antenna; or
a first low-noise amplifier configured to amplify a signal received from the first antenna for reception by the integrated circuit;
providing a second antenna; and
providing a second module located adjacent to the second antenna, wherein the second module comprises at least one of:
a second power amplifier configured to amplify a second signal received from the integrated circuit for transmission by the second antenna, or
a second low-noise amplifier configured to amplify a signal received from the second antenna for reception by the integrated circuit,
wherein a distribution of the first and second modules throughout the apparatus is in relation to an amount of heat produced by the first module during amplification of the first signal and an amount of heat produced by the second module during amplification of the second signal.

34. The method of claim 33, wherein the providing the first module comprises:
providing the first module at a location separate from a location of the integrated circuit.

35. The method of claim 33, further comprising:
providing a feed line connecting the first antenna and the first module and a feed line connecting the first module and the integrated circuit,
wherein a length of the feed line connecting the first antenna and the first module is less than a length of the feed line connecting the first module and the integrated circuit.

36. The method of claim 33, wherein the first module includes the first power amplifier and the first low-noise amplifier and providing the first module comprises:
providing a switching mechanism configured to switch operation of the first module between a transmission mode and a reception mode.

37. The method of claim 36, wherein the providing the first module further comprises:
providing a control mechanism configured to select the operation of the first module between the transmission mode and the reception mode.

38. The method of claim 36, wherein the providing the first module further comprises providing a phase shifter configured to at least one of:
shift a phase of the signal received from the integrated circuit prior to amplification; or
shift a phase of the signal received from the first antenna for transmission to the integrated circuit.

39. The method of claim 38, wherein the providing the first module further comprises:
providing a control mechanism configured to control amplitude or phase shift of a signal output by the first module.

40. The method of claim 33,
wherein the first and second antennas and the first and second modules are provided on a common substrate.
